(19) United States
(12) Patent Application Publication
(10) Pub. No.: US 2026/0279733 A1
(43) Pub. Date: Sep. 17, 2026

(54) ELECTROSTATIC CHUCK DEVICE

(71) Applicant: SUMITOMO OSAKA CEMENT CO., LTD., Tokyo (JP)

(72) Inventors: Satoyoshi INUI, Tokyo (JP); Takeshi OTSUKA, Tokyo (JP); Megumi OOTOMO, Tokyo (JP); Yuki KINPARA, Tokyo (JP)

(73) Assignee: SUMITOMO OSAKA CEMENT CO., LTD., Tokyo (JP)

(21) Appl. No.: 19/168,225

(22) PCT Filed: Mar. 29, 2024
(86) PCT No.: PCT/JP2024/013090

§ 371 Date: Sep. 23, 2025

(30) Foreign Application Priority Data
Mar. 30, 2023 (JP) 2023-055653

(51) Int. Cl. H01J 37/32; H10P 72/00; H10P 72/72

(52) U.S. Cl. CPC H01J 37/3244; H01J 37/32715; H10P 72/0421; H10P 72/0434; H10P 72/722

(57) ABSTRACT

Provided is an electrostatic chuck device including: an electrostatic chuck plate including a dielectric substrate having a placement surface on which a sample is mounted, and an adsorption electrode located inside the dielectric substrate; and a base that supports the electrostatic chuck plate from a side opposite to the placement surface, in which the electrostatic chuck plate has a gas hole passing through the electrostatic chuck plate in a thickness direction of the electrostatic chuck plate, a gas hole member allowing a gas to pass is provided in the gas hole, and volume resistivity of a material of the gas hole member is 1.0×10³ Ω·cm or more and 1.0×10¹⁰ Ω·cm or less.

This application is a National Stage Application of PCT/JP2024/013090, filed Mar. 29, 2024, which claims benefit of priority to Japanese Patent Application No. 2023-055653 filed on Mar. 30, 2023, and which applications are incorporated herein by reference. To the extent appropriate, a claim of priority is made to each of the above disclosed applications.

### TECHNICAL FIELD

The present invention relates to an electrostatic chuck device.

This application claims priority based on Japanese Patent Application No. 2023-055653 filed on Mar. 30, 2023, the content of which is incorporated herein by reference.

### BACKGROUND

In a semiconductor manufacturing process, an electrostatic chuck device that holds a semiconductor wafer in a vacuum environment is used. In the electrostatic chuck device, a plate-shaped sample such as a semiconductor wafer is placed on a placement surface, and an electrostatic force is generated between the plate-shaped sample and an internal electrode to adsorb and fix the plate-shaped sample. In addition, the electrostatic chuck device may be provided with a through-hole for supplying a gas to the placement surface in order to cool the semiconductor wafer to be mounted (for example, Patent Literature No. 1). In the following description, the “through-hole for supplying gas to the placement surface” is referred to as a “gas hole”.

The through-hole for gas supply may be a starting point of discharge that leads to a damage to the semiconductor wafer. In order to suppress such discharge, Patent Literature No. 2 proposes to install a gas plug mainly consisting of silicon carbide in the gas hole.

### CITATION LIST

### Patent Literature

Patent Literature No. 1: Japanese Laid-open Patent Publication No. 2017-157726
Patent Literature No. 2: Pamphlet of International Publication No. WO2020/203680

### SUMMARY OF INVENTION

### Technical Problem

In recent years, in a plasma etching device for manufacturing a semiconductor, high power is required for deep hole processing due to multilayering of a DRAM, a 3D-NAND, and the like. Therefore, it is required to suppress abnormal discharge that occurs near the gas hole.

The present invention has been made in view of such circumstances, and an object of the present invention is to provide an electrostatic chuck device capable of suppressing abnormal discharge near a gas hole.

### Solution to Problem

In order to achieve the above-described object, one aspect of the present invention includes the following aspects.
[1] An electrostatic chuck device including: an electrostatic chuck plate including a dielectric substrate having a placement surface on which a sample is mounted, and an adsorption electrode located inside the dielectric substrate; and a base that supports the electrostatic chuck plate from a side opposite to the placement surface, in which the electrostatic chuck plate has a gas hole passing through the electrostatic chuck plate in a thickness direction of the electrostatic chuck plate, a gas hole member allowing a gas for cooling the sample to pass is provided in the gas hole, and volume resistivity of a material of the gas hole member is 1.0×10³ Ω·cm or more and 1.0×10¹⁰ Ω·cm or less.
[2] The electrostatic chuck device according to [1], in which the material of the gas hole member is a composite material of an insulating material and a conductive material.
[3] The electrostatic chuck device according to [2], in which the dielectric substrate and the gas hole member are formed of the same material.
[4] The electrostatic chuck device according to any one of [1] to [3], in which the gas hole member is a porous body.
[5] The electrostatic chuck device according to any one of [1] to [4], in which the gas hole member has one or more fine holes having a diameter of 0.03 mm or more and 0.15 mm or less which pass through the gas hole member in a thickness direction.
[6] An electrostatic chuck device including: an electrostatic chuck plate including a dielectric substrate having a placement surface on which a sample is mounted, and an adsorption electrode located inside the dielectric substrate; and a base that supports the electrostatic chuck plate from a side opposite to the placement surface, in which the electrostatic chuck plate has a gas hole passing through the electrostatic chuck plate in a thickness direction of the electrostatic chuck plate, the dielectric substrate includes a gas hole forming portion at a position which overlaps the gas hole in a plan view, the gas hole includes, at the gas hole forming portion, a recessed portion which is provided on a surface which is opposite to the placement surface and a fine hole which is opened from the placement surface to the recessed portion, a diameter of the fine hole is 0.03 mm or more and 0.15 mm or less, and volume resistivity of a material of the gas hole forming portion is 1.0×10³ Ω·cm or more and 1.0×10¹⁰ Ω·cm or less.
[7] The electrostatic chuck device according to [6], in which the dielectric substrate and the gas hole forming portion are formed of the same material.

### Advantageous Effects of Invention

According to the present invention, it is possible to provide an electrostatic chuck device capable of suppressing abnormal discharge near a gas hole.

### BRIEF DESCRIPTION OF DRAWINGS

FIG. 1 A sectional schematic view representing an example of an electrostatic chuck device 1A.

FIG. 2 A schematic sectional view representing an example of an electrostatic chuck device 1B.

FIG. 3 A process diagram representing a method of manufacturing the electrostatic chuck device 1B.

FIG. 4 A process diagram representing a method of manufacturing the electrostatic chuck device 1B.

FIG. 5 A process diagram representing a method of manufacturing the electrostatic chuck device 1B.

FIG. 6 An explanatory view of an electrostatic chuck plate 2C.

### DESCRIPTION OF EMBODIMENTS

Hereinafter, a preferable example of each of embodiments of an electrostatic chuck device according to the present invention will be described with reference to the drawings. Note that in all of the following drawings, dimensions, ratios, and the like of each component may be displayed differently as appropriate to make the drawings easier to understand.

In addition, the present embodiments will be described in detail for better understanding the gist of the invention, and the present invention is not limited unless otherwise specified. For example, unless otherwise specified, conditions such as materials, amounts, types, numbers, sizes, ratios, temperatures, and the like may be changed, added, or omitted as necessary. In the embodiments described below, preferred examples may be exchanged or shared.

### First Embodiment

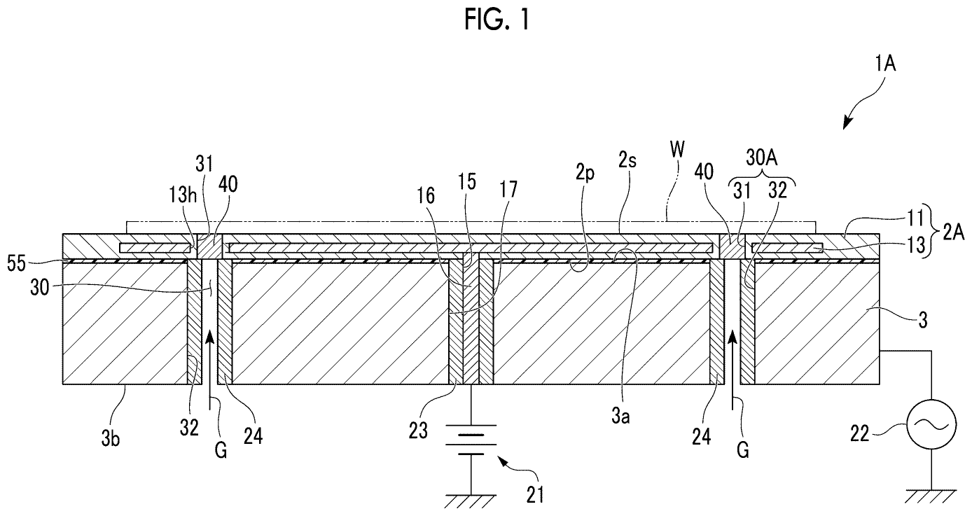

FIG. 1 is a schematic sectional view showing an electrostatic chuck device 1A of a first embodiment. The electrostatic chuck device 1A includes an electrostatic chuck plate 2A having a placement surface 2s on which a sample (a wafer W) is mounted, and a base 3 that supports the electrostatic chuck plate 2A from a side opposite to the placement surface 2s (a rear surface 2p side). Note that in an outer peripheral portion of an upper surface of the electrostatic chuck plate 2A, a focus ring that surrounds the wafer W is disposed.

Hereinafter, each configuration will be described in order.

### <<Electrostatic Chuck Plate>>

The electrostatic chuck plate 2A includes a dielectric substrate 11 and an adsorption electrode 13 positioned inside the dielectric substrate 11. The electrostatic chuck plate 2A adsorbs the wafer W on the placement surface 2s of the dielectric substrate 11.

In the following description, each part of the electrostatic chuck device 1A will be described on the assumption that with respect to the electrostatic chuck plate 2A, a side on which the wafer W is mounted is set as an upper side and a base 3 side is set as a lower side. That is, in the electrostatic chuck plate 2A, an upper and lower direction will be referred to as a thickness direction. Note that the upper and lower direction is merely a direction used for simplification of description, and does not limit the posture of the electrostatic chuck device 1A during use.

### (Dielectric Substrate)

The dielectric substrate 11 has a circular plate shape in a plan view. Note that in the present embodiment, the “plan view” refers to a field of view when viewed in the thickness direction of the electrostatic chuck device 1A, that is, from the upper side. The dielectric substrate 11 has the placement surface 2s on which the wafer W is placed, and a rear surface 2p that faces a side opposite to the placement surface 2s. On the placement surface 2s, for example, a plurality of protruding portions (not shown) are formed at predetermined intervals. The placement surface 2s supports the wafer W at tip portions of the plurality of protruding portions.

The dielectric substrate 11 is made of a sintered body having a sufficient mechanical strength and durability against corrosive gases and plasmas. As the dielectric material that constitutes the dielectric substrate 11, ceramics having mechanical strength and durability against corrosive gases and plasmas of the corrosive gas are preferably used.

As the ceramic that constitutes the dielectric substrate 11, for example, an insulating material such as an aluminum oxide (Al₂O₃) sintered body or an aluminum nitride (AlN) sintered body, Al₂O₃—SiC that is a composite sintered body (composite material) of an aluminum oxide (Al₂O₃) that is an insulating material and a silicon carbide (SiC) that is a conductive material, and the like are preferably used. Particularly, from the viewpoint of dielectric characteristics at a high temperature, corrosion resistance, plasma resistance, and heat resistance, a material constituting the dielectric substrate 11 is preferably Al₂O₃—SiC.

Volume resistivity of the material of the dielectric substrate 11 can be arbitrarily selected, but is preferably 1.0×10¹³ Ω·cm or more. When the volume resistivity is 10¹³ Ω·cm or more, charges that exhibit an adsorption force are generated on the surface by applying a voltage to the dielectric material, and the dielectric material functions as a Coulomb type electrostatic chuck device. The upper limit of the volume resistivity of the dielectric material can be arbitrarily selected, and may be 10¹⁷ Ω·cm or less, 10¹⁶ Ω·cm or less, or 10¹⁵ Ω·cm or less.

### (Adsorption Electrode)

The adsorption electrode 13 is disposed inside the dielectric substrate 11. The adsorption electrode 13 extends in a plate shape along the placement surface 2s of the dielectric substrate 11. By applying a voltage, the adsorption electrode 13 generates an electrostatic adsorption force to hold the wafer W on the placement surface 2s of the dielectric substrate 11.

The adsorption electrode 13 is made of a composite of an insulating material and a conductive material. The insulating material contained in the adsorption electrode 13 is not particularly limited, and is preferably at least one selected from the group consisting of aluminum oxide (Al₂O₃), aluminum nitride (AlN), silicon nitride (Si₃N₄), yttrium oxide (III) (Y₂O₃), yttrium aluminum garnet (YAG), and SmAlO₃. The conductive material contained in the adsorption electrode 13 is preferably at least one selected from the group consisting of molybdenum carbide (Mo₂C), molybdenum (Mo), tungsten carbide (WC), tungsten (W), tantalum carbide (TaC), tantalum (Ta), silicon carbide (SiC), carbon black, carbon nanotubes, and carbon nanofibers.

The thickness of the electrostatic chuck plate 2A can be arbitrarily selected, but is preferably 0.5 mm or more and 6 mm or less. For example, the thickness may be 1.0 mm or more and 5.5 mm or less, 1.5 mm or more and 5.0 mm or less, 2.0 mm or more and 4.0 mm or less, or the like. When the thickness of the electrostatic chuck plate 2A is 0.5 mm or more, a withstanding voltage of the electrostatic chuck plate 2A is increased. In addition, when the thickness of the electrostatic chuck plate 2A is 6 mm or less, heat capacity of the electrostatic chuck plate 2A is reduced. Therefore, it is easy to keep a temperature of the plate-shaped sample, which is a treatment target, uniform during a plasma treatment.

### <<Base>>

The base 3 supports the electrostatic chuck plate 2A from the lower side. The base 3 has a support surface 3a facing upper side, and a lower surface 3b facing a side opposite to the support surface 3a. The support surface 3a faces the rear surface 2p of the dielectric substrate 11 in the upper and lower direction. The support surface 3a is in contact with the rear surface 2p. That is, the base 3 supports the rear surface 2p of the dielectric substrate 11 on the support surface 3a.

The base 3 is a disk-shaped member in a plan view. The material constituting the base 3 is not particularly limited as long as the material is a metal, a composite material containing a metal, or a conductive ceramic having excellent thermal conductivity, electric conductivity, and workability, or a composite material (Metal Matrix Composition (MMC)) of a metal and a ceramic. As the material for the base 3, for example, an alloy containing aluminum (Al), copper (Cu), stainless steel (SUS), titanium (Ti), or the like, or conductive ceramics are preferably used. The material constituting the base 3 is preferably an aluminum alloy from the viewpoints of thermal conductivity, electric conductivity, and workability.

It is preferable that a surface of the base 3 that is exposed to plasmas is subjected to an alumite treatment or resin coating with a polyimide-based resin. In addition, it is more preferable that the entire surface of the base 3 is subjected to the alumite treatment or the resin coating. By subjecting the base 3 to the alumite treatment or the resin coating, resistance to plasmas in the base 3 is improved, and abnormal discharge on the surface of the base 3 is suppressed. Accordingly, the plasma stability of the base 3 can be improved, and surface scratches of the base 3 can also be prevented.

The inside of the base 3 may be configured to have a flow path through which a refrigerant circulates. As the refrigerant flowing in the flow path, water, a He gas, a N₂ gas, or the like is adopted. The flow path may be configured to extend along the support surface 3a. The refrigerant in the flow path cools down the entire base 3 and cools down the electrostatic chuck plate 2A via the support surface 3a.

The body of the base 3 has a function as an internal electrode for generating plasmas. The body of the base 3 is connected to an external high-frequency power supply 22 through a matching device (not shown).

The base 3 is fixed to the electrostatic chuck plate 2A through an adhesive. That is, an adhesive layer 55 that bonds the electrostatic chuck plate 2A and the base 3 to each other is provided between the electrostatic chuck plate 2A and the base 3. The adhesive layer 55 is interposed between the rear surface 2p of the electrostatic chuck plate 2A and the support surface 3a of the base 3, and the electrostatic chuck plate 2A and the base 3 are bonded and integrated. A heater that heats the electrostatic chuck plate 2A may be embedded in the adhesive layer 55.

As the adhesive used for the adhesive layer 55, an adhesive having heat resistance in a temperature range of −20° C. to 150° C. is preferable, and for example, an acrylic-based resin, a silicone-based resin, an epoxy-based resin, or the like is preferable.

The electrostatic chuck plate 2A and the base 3 integrated with the adhesive layer 55 are provided with a terminal through-hole 17 passing through a part of the base 3 and the dielectric substrate 11 in the thickness direction. A power supply terminal 16 for applying a DC voltage to the adsorption electrode 13 is inserted into the terminal through-hole 17, and is electrically connected to the adsorption electrode 13. A terminal insulator 23 having an insulating property is provided on an outer peripheral side of the power supply terminal 16. The terminal insulator 23 accommodates the power supply terminal 16 in a through-hole 15 provided in the terminal insulator 23, and insulates the base 3 and the power supply terminal 16.

The power supply terminal 16 is connected to an external power supply 21. The power supply 21 applies a voltage to the adsorption electrode 13. The number, shape, and the like of the power supply terminal 16 are determined depending on a type of the adsorption electrode 13, that is, whether the adsorption electrode 13 is a monopolar type or a bipolar type.

### <<Gas Hole, Gas Hole Member>>

A plurality of gas holes 30A passing through the electrostatic chuck plate 2A, the base 3, and the adhesive layer 55 in the upper and lower direction are provided. The number and position of the gas holes 30A can be arbitrarily selected. A gas hole member 40 is provided at an end portion of the gas hole 30A on the placement surface 2s side. The gas holes 30A are connected to a gas supply device (not shown). The gas holes 30A are provided to supply a gas G for cooling down a sample such as helium (He) to the placement surface 2s of the electrostatic chuck plate 2A and to cool down the wafer W placed on the placement surface 2s.

### (Gas Hole)

The gas hole 30A includes a first through-hole 31 that is a portion passing through the electrostatic chuck plate 2A, and a second through-hole 32 that is a portion passing through the base 3. That is, the first through-hole 31 is provided in the electrostatic chuck plate 2A, and the second through-hole 32 is provided in the base 3. Central axes of the first through-hole 31 and the second through-hole 32 match with each other. The first through-hole 31 and the second through-hole 32 communicate with each other.

The shape (internal shape) of the first through-hole 31 may be a straight shape (for example, a columnar shape or a truncated cone shape) having a smooth inner surface without a step, may be a shape having one or more steps, and/or may be a shape having one or more inclined surfaces. The shape may be a circular shape in a plan view. The first through-hole 31 may have one or more vertical surfaces (curved surfaces), one or more steps, and/or one or more inclined surfaces on the inner surface thereof. With respect to a cross-sectional shape in a lateral direction of the first through-hole 31, the cross-sectional shape in the lateral direction and an inner diameter thereof may be constant, or one or both of the cross-sectional shape and the inner diameter may vary continuously and/or stepwise change in the thickness direction. For example, the inner diameter of the first through-hole 31 may decrease or may increase gradually or stepwise in the thickness direction, or may be combined with each other as desired. The number of steps or an angle of the steps can be arbitrarily selected. For example, the number may be 1 to 10, 2 to 8, or 3 to 6, and the angle may be 10 to 150 degrees, 30 to 90 degrees, or 45 to 60 degrees. An inner shape of the first through-hole 31 may coincide with an outer shape of a gas hole member or a gas hole forming portion to be described later.

The first through-hole 31 passes through the dielectric substrate 11 of the electrostatic chuck plate 2A in the thickness direction. In addition, a retreat hole 13h surrounding the first through-hole 31 is provided between the adsorption electrode 13 of the electrostatic chuck plate 2A and the first through-hole 31. A portion of the dielectric substrate 11 is disposed inside the retreat hole 13h. Therefore, the adsorption electrode 13 is not exposed from an inner peripheral surface of the first through-hole 31.

The second through-hole 32 is connected to the first through-hole 31. A tubular insulator 24 may be inserted into the second through-hole 32. An outer peripheral surface of the insulator 24 is fixed to the second through-hole 32, for example, by an adhesive. The inside of the insulator 24 functions as a passage route 30 of the gas G.

The insulator 24 is made of, for example, a ceramic as a forming material. That is, the insulator 24 is made of an insulating material. The insulator 24 has durability against plasmas. As the ceramics constituting the insulator 24, ceramics containing one or more selected from AlN, Al₂O₃, Si₃N₄, ZrO₂, sialon, and boron nitride (BN) can be adopted.

### (Gas Hole Member)

The gas hole member 40 is fitted into the first through-hole 31 and is in close contact with an inner wall of the first through-hole 31. The shape of the gas hole member 40 is a shape complementary to the shape of the first through-hole 31. For example, in a case where the first through-hole 31 has a circular shape in a plan view and a shape extending in the upper and lower direction in a uniform cross-sectional shape, the gas hole member 40 has a columnar shape extending in the upper and lower direction.

Note that in FIG. 1, a height of the gas hole member 40 is shown to coincide with a length of the first through-hole 31 in the upper and lower direction, but the present invention is not limited thereto. The gas hole member 40 may be shorter than the length of the first through-hole 31 in the upper and lower direction. In this case, it is assumed that an upper end of the gas hole member 40 coincides with the upper end of the first through-hole 31 and is located at the same height as in the placement surface 2s.

The gas hole member 40 allows the gas G flowing inside the gas holes 30A to pass therethrough. A structure for allowing the gas G to pass through the gas hole member 40 is not particularly limited.

For example, the gas hole member 40 may be a porous body. In a case where the gas hole member 40 is a porous body, micropores in the porous body are connected to each other, and are continuous in the upper and lower direction of the gas hole member 40 to constitute a flow path of the gas G in the gas hole member 40.

A pore size of the porous body is not particularly limited as long as the gas G can be sufficiently supplied to the placement surface 2s and abnormal discharge is suppressed. The pore size of the porous body can be arbitrarily selected, and for example, may be 30 μm or more and 150 μm or less or 50 μm or more and 100 μm or less. When the pore size of the gas hole member 40 is too small, the gas G cannot be sufficiently supplied to the placement surface 2s, and when the pore size is too large, a potential change near an upper end of the first through-hole 31 is large, and an electric field generated is also large. Therefore, there is a case where it is difficult to suppress the abnormal discharge.

A porosity of the porous body is not particularly limited as long as the gas G can be sufficiently supplied to the placement surface 2s, and may be, for example, 30% or more and 70% or less. The porosity may be 35% or more and 65% or less, 45% or more and 55% or less, or the like.

Note that here, the “porosity” is a ratio of a total volume of micropores to a predetermined unit volume of the porous body. The porosity may be a value obtained from a ratio between a true density of the forming material of the porous body to an apparent density of the porous body, or may be obtained by measuring the volume of micropores per unit volume. The higher the porosity of the porous body, the more micropores, and the easier the gas G flows out.

In addition, the gas hole member 40 may have one or more fine holes passing therethrough in the thickness direction. In a case where the gas hole member 40 has the fine holes (through-holes or a part of the through-holes), a diameter of the fine holes is not particularly limited as long as the gas G can be sufficiently supplied to the placement surface 2s. The diameter of the fine holes can be arbitrarily selected, but is, for example, 0.03 mm or more and 0.15 mm or less. For example, the thickness of the resin layer may be 0.05 mm or more and 0.13 mm or less, or 0.07 mm or more and 0.10 mm or less. The diameter of the fine holes may be constant in the thickness direction, but may not be constant as necessary.

The shape (internal shape) of the fine holes is not particularly limited as long as the gas G can pass therethrough, and may be a rectangular shape, a cubic shape, or a columnar shape. The shape of the fine holes may be a regular shape or an irregular shape. The fine holes may have a polygonal shape such as a circular shape or a square shape in a plan view.

The number of fine holes may be appropriately adjusted to a number that can achieve both the gas permeability and the abnormal discharge suppression. The number of fine holes can be arbitrarily selected, and may be, for example, 1 to 200, 5 to 180, 10 to 160, 30 to 100, or the like. The fine holes can be formed by various methods. For example, the fine holes may be formed in a molded body without the fine holes hole by laser processing or mechanical processing.

In addition, the gas hole member 40 may be a porous body having one or more fine holes passing therethrough in the thickness direction.

The volume resistivity of the material of the gas hole member 40 is 1.0×10³ Ω·cm or more and 1.0×10¹⁰ Ω·cm or less, may be 1.0×10⁴ Ω·cm or more and 1.0×10⁹ Ω·cm or less, may be 1.0×10⁵ Ω·cm or more and 1.0×10⁸ Ω·cm or less, or may be 1.0×10⁶ Ω·cm or more and 1.0×10⁷ Ω·cm or less.

In a case where the volume resistivity of the gas hole member 40 is less than 1.0×10³ Ω·cm, electricity is likely to flow, and thus heat generation near the first through-hole 31 increases. Accordingly, plasma resistance of the gas hole member 40 tends to decrease, which is not preferable. When the volume resistivity of the gas hole member 40 exceeds 1.0×10¹⁰ Ω·cm, there is a tendency that the abnormal discharge generated at the periphery of the first through-hole 31 cannot be sufficiently suppressed, which is not preferable.

In the related field, the gas hole member is generally formed of an insulating material. However, with the recent high power of the semiconductor manufacturing device, it is difficult to suppress occurrence of the abnormal discharge in the insulating gas hole member.

Therefore, as a result of various examinations made by the present inventors through simulations, surprisingly, in a specific case, it has been found that a side surface portion of the gas hole member has electric conductivity, so that even when the electrostatic chuck device is exposed to plasmas, an equipotential is maintained from an upper end to a lower end of the gas hole member, that is, the abnormal discharge is not caused. As a result of the examinations, the present inventors came up with an idea of using a material having a predetermined electric conductivity, that is, volume resistivity of 1.0×10³ Ω·cm or more and 1.0×10¹⁰ Ω·cm or less for the gas hole member.

A method of measuring the volume resistivity of the gas hole member 40 is not particularly limited, but for example, the volume resistivity can be measured by a DC three-terminal method.

The material of the gas hole member 40 is preferably a composite material of an insulating material and a conductive material. The composite material can be adjusted to a desired volume resistivity by adjusting types of the insulating material and the conductive material and a mixing ratio of the insulating material and the conductive material.

In the present specification, the term “insulating” means that the volume resistivity is 1×10¹³ Ω·cm or more. The term “insulating” material is a material having volume resistivity of 1×10¹³ Ω·cm or more.

In addition, in the present specification, the term “conductive” means that the volume resistivity is less than 1×10¹³ Ω·cm. The term “conductive” material is a material having volume resistivity of less than 1×10¹³ Ω·cm.

Since the material of the gas hole member 40 is a composite material of the insulating material and the conductive material, the volume resistivity of the gas hole member 40 can be easily adjusted to a desired range. Therefore, it is possible to suppress the abnormal discharge, and it is possible to easily obtain the gas hole member 40 having excellent plasma resistance.

The insulating material contained in the gas hole member 40 is not particularly limited, and is preferably at least one selected from the group consisting of, for example, Al₂O₃, AlN, silicon oxide (SiO₂), silicon nitride (Si₃N₄), yttrium oxide (III) (Y₂O₃), calcium oxide (CaO), magnesium oxide (MgO), zirconium oxide (ZrO₂), yttrium aluminum garnet (YAG), and SmAlO₃.

The conductive material contained in the gas hole member 40 is preferably at least one selected from the group consisting of molybdenum carbide (Mo₂C), molybdenum (Mo), tungsten carbide (WC), tungsten (W), tantalum carbide (TaC), tantalum (Ta), silicon carbide (SiC), carbon black, carbon nanotubes, and carbon nanofibers.

It is preferable that the gas hole member 40 uses the same material as the dielectric substrate 11 as a forming material. The same material as the forming material may mean that the material is manufactured from the same forming material, or may mean that the material is formed by using the same raw material (material). The forming material may be a composite material or a mixture. Note that a proportion (mixing ratio), a shape, and/or a size of the material or the raw material contained in the forming material such as the composite material or the mixture may be different. It is preferable to use Al₂O₃—SiC for the gas hole member 40. The gas hole member 40 formed of Al₂O₃—SiC can suppress the abnormal discharge and has excellent plasma resistance.

The size of the gas hole member 40 is not particularly limited as long as the gas hole member 40 can be provided in the first through-hole 31. For example, a diameter of the gas hole member 40 may be 0.5 mm or more and 2.5 mm or less. The diameter may be 1.0 mm or more and 2.2 mm or less, or 1.5 mm or more and 2.0 mm or less. The thickness of the gas hole member 40 can be arbitrarily selected, and may be, for example, 0.1 mm or more and 10 mm or less, 0.5 mm or more and 6 mm or less, or 1 mm or more and 5 mm or less. The thickness of the first resin layer may be 3 mm or more and 8 mm or less, or may be 5 mm or more and 7 mm or less. The thickness of the gas hole member 40 can be selected as necessary, and may be 5% to 100%, 10% to 90%, 20% to 80%, or 30% to 70% of the thickness of the dielectric substrate 11.

The gas hole member 40 can be manufactured, for example, by the following method.

First, the above-described insulating material and conductive material and, as appropriate, a binder, a dispersant, a solvent, or the like are mixed to prepare slurry.

Next, a pore forming agent is further added to the obtained slurry.

Next, the pore forming agent-containing slurry is put into a mold having a desired shape and is calcinated, so that the gas hole member 40 can be obtained. The pore forming agent comes into contact with each other during a process of drying the slurry, and further disappears during calcination. Accordingly, in the obtained gas hole member 40, micropores continuously extending in the upper and lower direction of the gas hole member 40 are formed at positions where the pore forming agent is present. The amount of the pore forming agent is an amount at which the micropores communicating with each other are formed in the gas hole member 40 to be formed. A specific usage amount may be confirmed in advance by a preliminary experiment.

Alternatively, a mold made of a porous member such as a urethane sponge is impregnated with the obtained slurry, and the slurry is dried to remove excess slurry, and then is calcinated, so that the gas hole member 40 can be obtained. Processing may be further performed after the calcination as necessary. The slurry may contain the pore forming agent or may not contain the pore forming agent.

The mold of the porous member disappears at the time of calcination. Accordingly, in the obtained gas hole member 40, micropores that are continuous in the upper and lower direction of the gas hole member 40 are formed at positions where the mold of the porous member is present.

Alternatively, a photosensitive material such as a photocurable resin is further added to the slurry, and the obtained photosensitive material-containing slurry is molded into a desired shape by using an optical molding device to obtain a temporary molded body, and the temporary molded body is calcinated to obtain the gas hole member 40. The photosensitive material disappears at the time of calcination. During the optical molding, since a plurality of through-holes are formed in the temporary molded body, in the obtained gas hole member 40, fine holes passing through the gas hole member 40 are formed at positions corresponding to the through-holes.

The through-holes formed by the optical molding may linearly pass through the inside of the temporary molded body, or may be curved or bent inside the temporary molded body.

Further, a pore forming agent may be added to the slurry to which the photosensitive material is added, and micropores may be formed in the obtained gas hole member.

Fine holes may be formed in the gas hole member 40 manufactured in this way by laser processing or mechanical processing.

In addition, the slurry may be molded and calcinated into any shape, for example, a columnar shape, and the gas hole member 40 may be formed by forming fine holes in an obtained columnar sintered body by laser processing or mechanical processing. That is, the gas hole member 40 may be formed without using the pore forming agent, the mold of the porous member, and the photosensitive material.

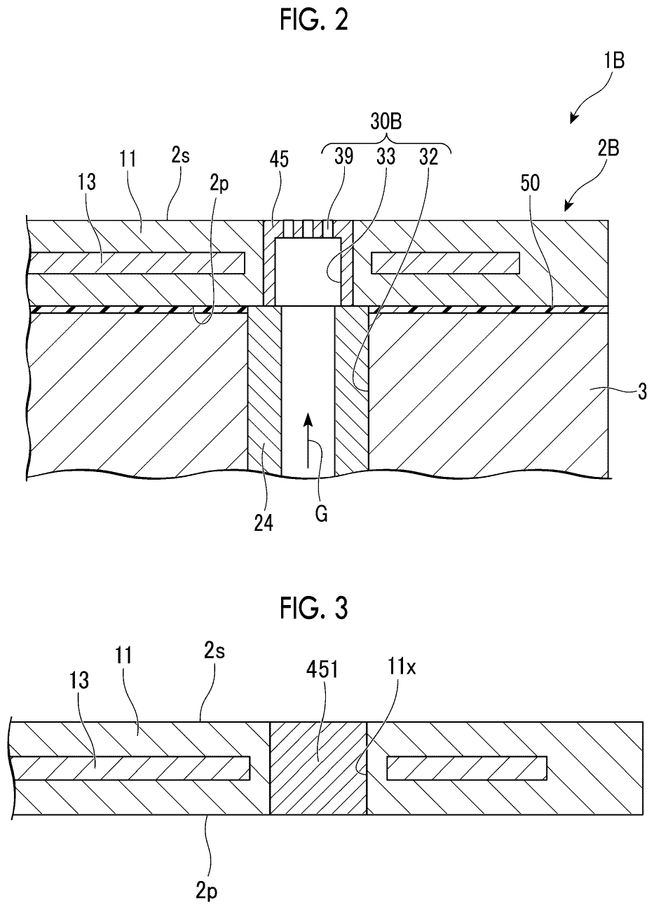

The fine holes may pass through the columnar sintered body in the upper and lower direction. Alternatively, the sintered body may further have a recessed portion. For example, a recessed portion 33 and fine holes 39 as shown in FIG. 2 may be formed in the obtained columnar sintered body. The shape of the recessed portion can be arbitrarily selected, and may be, for example, a valley portion having a columnar shape or a prismatic shape.

The gas hole member 40 in which the gas hole is formed before being fitted to the first through-hole 31 can be inserted or press-fitted into the first through-hole 31 provided in the dielectric substrate 11 and can be fixed inside the gas hole by calcination as necessary. A calcination temperature can be arbitrarily selected, and 1600° C. to 1850° C. is exemplified. Calcination may be performed, for example, in a state of being pressurized in a range of 1 MPa to 50 MPa. Note that in a case where the gas hole member 40 is inserted into or press-fitted into the first through-hole 31, an adhesive member may be applied in advance to at least a part of the side surface portion or the bottom surface portion of the gas hole member 40 and then the gas hole member 40 may be inserted into or press-fitted into the first through-hole 31.

In the electrostatic chuck device 1A as described above, the first through-hole 31 is blocked by the gas hole member 40. Since the volume resistivity of the gas hole member 40 is 1.0×10³ Ω·cm or more and 1.0×10¹⁰ Ω·cm or less, the gas hole member 40 suppresses the abnormal discharge in the electrostatic chuck device 1A. As a result, a highly reliable electrostatic chuck device 1A can be provided.

### Second Embodiment

FIGS. 2 to 5 are explanatory views showing an example of an electrostatic chuck device 1B and a manufacturing method thereof according to a second embodiment. In the electrostatic chuck device 1B of the present embodiment, a configuration and/or a manufacturing method of a part of the electrostatic chuck plate are different as compared with the electrostatic chuck device 1A of the first embodiment, and the other configurations are common to those of the electrostatic chuck device 1A. Therefore, description will be made mainly on an electrostatic chuck plate 2B, and the description of configurations and conditions common to the electrostatic chuck device 1A will be omitted.

FIG. 2 is a schematic sectional view of the electrostatic chuck device 1B. As illustrated in FIG. 2, the electrostatic chuck plate 2B of the electrostatic chuck device 1B includes the dielectric substrate 11 and the adsorption electrode 13 located inside the dielectric substrate 11. The electrostatic chuck plate 2B adsorbs the wafer W on the placement surface 2s of the dielectric substrate 11.

A plurality of gas holes 30B passing through the electrostatic chuck plate 2B, the base 3, and an adhesive layer 50 in the upper and lower direction are provided. The gas holes 30B are configured to communicate with the recessed portion 33 and the fine holes 39 provided in the electrostatic chuck plate 2B and the second through-hole 32 provided in the base 3. The gas hole 30B is connected to a gas supply device (not shown).

The recessed portion 33 is provided in a gas hole forming portion 45 set in the dielectric substrate 11 of the electrostatic chuck plate 2B. The gas hole forming portion 45 is a part of the dielectric substrate 11. The gas hole forming portion 45 may be formed integrally with the dielectric substrate 11. In a plan view, the gas hole forming portion 45 overlaps the gas holes 30B. Note that examples of a shape, a size, and a material of the gas hole forming portion 45, the recessed portion 33, and the fine holes 39 may be the same as those of the example shown in the gas hole member 40. The gas hole forming portion 45 may include the gas hole member 40, may be formed only of the gas hole member 40, or may be formed by a combination of the gas hole member 40 and the dielectric substrate 11. For example, the gas hole forming portion 45 may be formed of the gas hole member 40 at an upper portion thereof and may be formed of a part of a dielectric substrate having a recessed portion at a lower portion thereof. In the electrostatic chuck plate 2B, the gas hole forming portion 45 may mean a portion overlapping the gas hole member 40 in a plan view, but is not limited to this example. For example, in a case where a diameter of the recessed portion 33 is smaller than a diameter of the gas hole member 40, the gas hole forming portion 45 may mean a portion overlapping the gas hole member 40 in a plan view. In a case where the diameter of the recessed portion 33 is larger than the diameter of the gas hole member 40, the gas hole forming portion 45 may mean a portion overlapping the recessed portion 33 in a plan view.

The material of the gas hole forming portion 45 may be the same material as that of the dielectric substrate 11, or may be a different material. The dielectric substrate 11 and the gas hole forming portion 45 may be formed of the same material as the forming material, but a ratio, a shape, and/or a size of the materials (raw materials) may be different. The volume resistivity of the material of the gas hole forming portion 45 can be set to the same numerical range as that of the above-described gas hole member 40. A length of the gas hole forming portion 45 in the upper and lower direction is preferably the same as the thickness of the dielectric substrate 11, but may be shorter than the thickness of the dielectric substrate 11 as necessary. In a case where the gas hole member 40 is included, when the length of the gas hole member 40 in the upper and lower direction is shorter than the thickness of the dielectric substrate 11, an upper end of the gas hole forming portion 45 coincides with an upper end of the first through-hole 31 and is at the same height position as in the placement surface 2s.

The recessed portion 33 is formed from the rear surface 2p of the dielectric substrate 11 toward the placement surface 2s side. The recessed portion 33 does not pass through the dielectric substrate 11.

A width (inner diameter) of the recessed portion 33 may be the same width, may be a narrow width, or may be a wide width as compared with a width of the gas hole forming portion 45 or the gas hole member 40. The inner wall of the recessed portion 33 is formed of a material of the gas hole forming portion 45 or the dielectric substrate 11. For example, the recessed portion 33 may be formed only in the gas hole member 40, may be formed only in the dielectric substrate other than the gas hole member, or may be continuously formed in both the gas hole member and the dielectric substrate.

The fine holes 39 pass through the gas hole forming portion 45 in the thickness direction and are open to the recessed portion 33. The gas hole forming portion 45 in which the fine holes 39 are formed has the same function as that of the above-described gas hole member 40.

FIGS. 3 to 5 are process diagrams showing an example of a method for manufacturing the electrostatic chuck device 1B. FIGS. 3 to 5 show an example of a method for manufacturing the electrostatic chuck plate 2B.

First, as shown in FIG. 3, a material having volume resistivity of 1.0×10³ Ω·cm or more and 1.0×10¹⁰ Ω·cm or less is put into a through-hole 11x provided at a position overlapping a gas hole in the dielectric substrate 11, and is sintered to be integrated with the dielectric substrate 11, thereby forming a gas hole forming portion 451. The material to be sintered is the same as the material of the above-described gas hole member 40, and a composite material of an insulating material and a conductive material can be adopted as an example. A sintering temperature can be arbitrarily selected from a temperature that allows integration by sintering, and 1600° C. to 1850° C. is exemplified. Calcination may be performed, for example, in a state of being pressurized in a range of 1 MPa to 50 MPa.

Note that a dielectric substrate 11 in which a material having volume resistivity of 1.0×10³ Ω·cm or more and 1.0×10¹⁰ Ω·cm or less is put into the through-hole 11x provided at a position overlapping a gas hole, and a dielectric substrate 11 that is not provided with the through-hole 11x may be laminated, sintered, and integrated to form the gas hole forming portion 451 only on the placement surface 2s side.

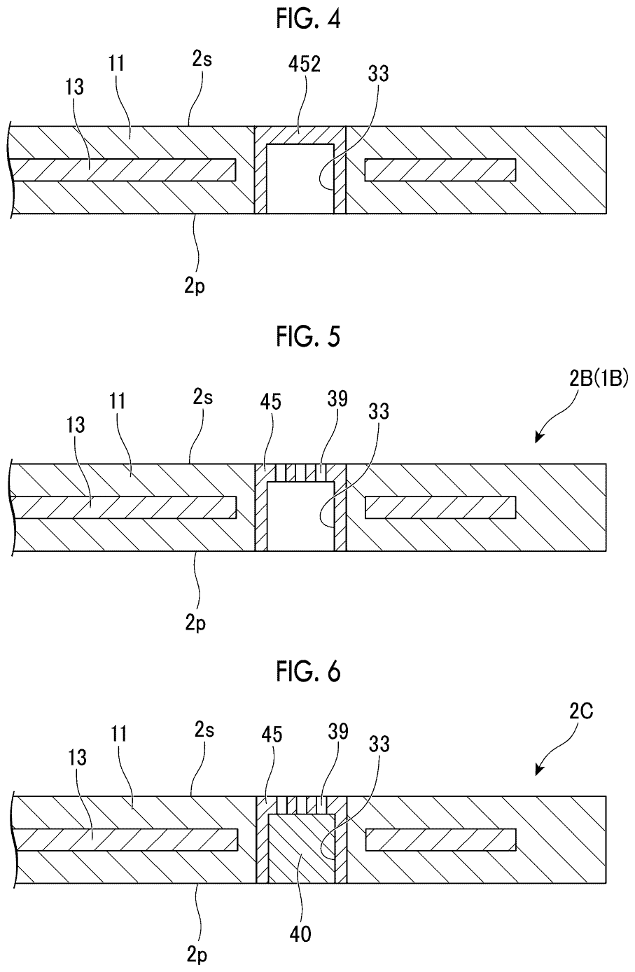

Next, as shown in FIG. 4, the gas hole forming portion 451 is subjected to counter boring from the rear surface 2p toward the placement surface 2s side, and a gas hole forming portion 452 having the recessed portion 33 is formed. A depth of the recessed portion 33 is arbitrary, and may be, for example, 10% to 30% or 30% to 50% or 50% to 70% or 70% to 90% of the thickness of the dielectric substrate 11.

Next, the dielectric substrate 11 is bonded to the base (refer to FIG. 2) (not shown), and the placement surface 2s is subjected to surface grinding. Then, as shown in FIG. 5, one or more fine holes 39 are formed. Accordingly, the electrostatic chuck plate 2B including the gas hole forming portion 45 and the electrostatic chuck device 1B including the electrostatic chuck plate 2B are obtained. Note that the order of the above processing may be changed as necessary.

For example, bonding to the base may be performed after the fine holes 39 are formed. Specifically, after the placement surface 2s of the dielectric substrate 11 is subjected to the surface grinding, as shown in FIG. 5, one or more fine holes 39 communicating with the recessed portion 33 are formed, and the electrostatic chuck plate 2B is obtained. Next, the electrostatic chuck plate 2B is bonded to the base (not shown) (refer to FIG. 2), and the electrostatic chuck device 1B including the electrostatic chuck plate 2B is obtained.

Note that as in an electrostatic chuck plate 2C shown in FIG. 6, a member similar to the gas hole member 40 of the first embodiment may be processed as necessary and fitted into the recessed portion 33.

Even in the electrostatic chuck device 1B including the above-described configuration, it is possible to suppress the abnormal discharge and to provide the electrostatic chuck device having high reliability.

Hereinabove, various embodiments of the present invention have been described. However, the configurations of the embodiments, a combination thereof, and the like are exemplary, and additions, omissions, replacements and other changes can be made for the configurations within a range not departing from the scope of the present invention. Further, the present invention is not limited to the embodiments.

### EXAMPLES

Hereinafter, the present invention will be more specifically described with reference to examples and comparative examples, but the present invention is not limited to examples. The following examples will be described by appropriately using the reference numerals used in the embodiments described above.

### Example 1

### “Preparation of Slurry”

As starting raw materials, silicon carbide (SiC) particles having an average particle diameter of 0.03 μm and aluminum oxide (Al₂O₃) particles having an average particle diameter of 0.1 μm were used.

The SiC particles and the Al₂O₃ particles were weighed so that the SiC particles accounted for 18% by mass of a total amount of the SiC particles and the Al₂O₃ particles. Next, the particles were put into distilled water containing a polycarboxylic acid-based dispersant. Slurry containing SiC particles and Al₂O₃ particles was obtained by performing a dispersion treatment on a dispersed solution into which SiC particles and Al₂O₃ particles were put by using an ultrasonic dispersion device and then performing crushing and mixing by using a two-flow particle collision type crushing and mixing device.

### “Preparation of Gas Hole Member”

A urethane sponge (mold for forming a porous member) was impregnated with the obtained slurry and was dried. Next, the obtained dried body was calcinated at 1800° C. for 48 hours in an Ar atmosphere to obtain a molded body. The urethane sponge portion disappeared by the calcination. The obtained molded body was ground, and the gas hole member of Example 1 was obtained.

### “Evaluation of Gas Hole Member”

### (Measurement of Volume Resistivity)

A test piece having a diameter of 28 mm and a thickness of 1 mm was obtained from the obtained molded body, and the resistivity of the gas hole member of Example 1 was measured by a DC three-terminal method using a resistivity measuring device and a digital ultra-high resistance/micro current meter (Model 5450, manufactured by ADC CORPORATION) with the test piece. A main electrode, a counter electrode, and a guard electrode are formed by screen printing a silver paste (US-202A, manufactured by Daiken Chemical Sales & Mfg. Co., Ltd.) on an upper surface and a lower surface of the test piece by using a screen printing machine (MODEL MEC-2400, manufactured by MITANI MICRONICS Co., Ltd.) and drying the silver paste at 150° C. in the air for 12 hours. A diameter of the main electrode was 1.45 cm, and an inner diameter of the guard electrode was 1.60 cm.

Measurement was performed at room temperature (24° C.) in the air, a DC voltage of 100 V was applied, and a current after charging for 1 minute was measured to obtain the volume resistance (Rv) of the test piece. Next, the volume resistivity (ρv) was calculated from the following Equation (1) using the thickness of the test piece and an electrode area.

$$ρ v = S / t \times Rv = S / t \times V / I \qquad ( 1 )$$

(S: effective area (cm²), t: thickness of a sintered body (cm), Rv: volume resistance (Ω), V: DC voltage (V), I: current (A))
   As a result, the volume resistivity of the test piece, that is, the gas hole member of Example 1 was 1.1×10⁵ Ω·cm.

### “Preparation of Electrostatic Chuck Device”

In the electrostatic chuck device having the configuration shown in FIG. 1, the gas hole member of Example 1 was inserted into the first through-hole 31 to obtain the electrostatic chuck device of Example 1.

### (Discharge Test)

The electrostatic chuck device 1 of Example 1 was operated to apply plasmas in a state in which the semiconductor wafer was adsorbed to the electrostatic chuck device 1. As a result, a discharge trace or the like was not found in the semiconductor wafer. That is, it was confirmed that the abnormal discharge was not observed and the discharge was suppressed.

### Example 2

A gas hole member, a dielectric substrate, an electrostatic chuck plate using the gas hole member and the dielectric substrate, and an electrostatic chuck device were manufactured by the following method.

### “Preparation of Gas Hole Member”

The slurry obtained in Example 1 was sprayed and dried with a spray dryer to obtain mixed particles of SiC and Al₂O₃. The obtained mixed particles were uniaxially press-molded at a press pressure of 8 MPa to obtain a molded body having a diameter of 320 mm and a thickness of 15 mm.

Next, the obtained molded body was heat-treated by raising the temperature to 385° C. at a temperature rising rate of 0.5° C./min in a nitrogen atmosphere without applying a pressing pressure, and moisture and a dispersant (contaminants) contained in the molded body were removed.

The obtained molded body was set in a graphite mold and pressure-sintering was performed. Specifically, the temperature of the molded body was raised to 1100° C. under a vacuum atmosphere at a press pressure of 5 MPa. Thereafter, the temperature was raised to 1800° C. under an argon atmosphere at a press pressure of 40 MPa to obtain a sintered body.

A part of the obtained sintered body was ground, and 15 columnar sintered bodies (gas hole members) having a diameter of 1.8 mm and a thickness of 2.8 mm were manufactured.

The volume resistivity of the columnar sintered body was measured in a similar manner as in Example 1. As a result, the volume resistivity of the sintered body of Example 2 was 1.1×10⁵ Ω·cm. Note that fine holes were formed in the sintered bodies by a method to be described later.

### “Preparation of Dielectric Substrate”

As starting raw materials, silicon carbide (SiC) particles having an average particle diameter of 0.03 μm and aluminum oxide (Al₂O₃) particles having an average particle diameter of 0.1 μm were used.

Aluminum oxide particles and silicon carbide particles were weighed so that the mass ratio became 95:5, and were put into distilled water containing a polycarboxylic acid-based dispersant to obtain a liquid mixture. The liquid mixture was subjected to a dispersion treatment with an ultrasonic dispersion device. Then, the mixture was crushed and mixed by using a two-flow particle collision type crushing and mixing device to obtain slurry.

Nitric acid was added to the obtained slurry to adjust a pH of the slurry to 6.5.

Next, the slurry having the pH adjusted to 6.5 was spray-dried with a spray dryer to obtain mixed particles containing silicon carbide and aluminum oxide.

Next, the obtained mixed particles were uniaxially press-molded at a press pressure of 8 MPa to obtain a molded body having a diameter of 320 mm and a thickness of 15 mm.

Subsequently, the molded body was subjected to a heat treatment by raising a temperature to 385° C. at a temperature rising rate of 0.5° C./min in a nitrogen atmosphere without applying a press pressure to remove moisture and a dispersant (contaminants).

The obtained molded body was set in a graphite mold and pressure-sintering was performed. As sintering conditions, a press pressure was set to 5 MPa in a vacuum atmosphere at a temperature up to 1100° C. Thereafter, sintering was performed at a temperature of 1800° C. and a press pressure of 40 MPa in an argon atmosphere.

The obtained sintered body was processed, and two molded bodies having a diameter of 310 mm and a thickness of 3 mm (molded bodies A and B) were manufactured.

Fifteen through-holes having a diameter of 2 mm for inserting the gas hole member were formed at a predetermined position in the molded body A. The gas hole member of Example 2 was inserted into each of 15 through-holes.

In the molded body B, a through-hole having a diameter of 3 mm was formed in a central portion thereof. A sintered body of aluminum oxide-tantalum carbide (30% by volume of tantalum carbide) was inserted into the formed through-hole and fixed by a columnar body processed to match the shape of the through-hole, and a power supply terminal was formed. Note that a hole for inserting the gas hole member is not formed in the molded body B.

### “Preparation of Adsorption Electrode”

A conductive dispersed solution was prepared by mixing aluminum oxide particles, needle-like carbon (0.1 μm in a lateral direction, and 2 μm in a longitudinal direction), and screen oil (terepineol). At that time, the needle-like carbon was 5% by volume with respect to the total amount of the aluminum oxide particles and the needle-like carbon.

Further, an insulating dispersant was prepared by mixing aluminum oxide and screen oil.

A screen printing device was used to print a conductive dispersed solution on a surface of the molded body B in a desired shape of the adsorption electrode. In addition, the insulating dispersant was printed on the surface of the molded body B at a position where the recessed portion 33 of the second embodiment is formed and in the vicinity of a position where the printed conductive dispersed solution is surrounded.

The molded body A into which the gas hole member is inserted is stacked on a side of the molded body B where the printing was performed, and heat is applied by using a hot press device to perform pressure bonding (40 MPa, 1800° C.) to obtain an electrostatic chuck plate. In this way, the gas hole member (gas hole forming portion) was formed.

The obtained electrostatic chuck plate was processed to have a thickness of 0.5 mm for the molded body A, a thickness of 4.0 mm for the molded body B, and an outer diameter of 293 mm. Next, an recessed portion (corresponding to the recessed portion 33 of the second embodiment) having a diameter of 1 mm and a depth of 4 mm was formed by boring a portion corresponding to a portion where the gas hole member is formed from the rear surface of the electrostatic chuck plate. Further, a lift pin insertion hole was formed in the electrostatic chuck plate.

Both surfaces (a surface on the molded body A side and a rear surface on the molded body B side) of the electrostatic chuck plate were surface-ground.

Next, a plurality of fine holes (corresponding to the fine holes 39 of the second embodiment) having a diameter of 0.1 mm were formed in each of the gas hole members by laser processing from the surface side of the electrostatic chuck plate. In this way, the electrostatic chuck plate of Example 2 including the gas hole member was obtained.

The electrostatic chuck plate of Example 2 and an aluminum base were bonded to each other by using a silicone-based adhesive to obtain the electrostatic chuck device of Example 2. As the base, a base in which a thermal spraying film is formed on an upper surface and a side surface was used.

As a result of performing a discharge test of the electrostatic chuck device 1 of Example 2 in a similar manner as in Example 1, it was confirmed that there was no discharge trace on the wafer and the abnormal discharge was suppressed.

### Example 3

An electrostatic chuck plate and an electrostatic chuck device of Example 3 were obtained in a similar manner as in Example 2 except that a gas hole member of Example 1 was processed and inserted into the recessed portion of the electrostatic chuck plate of Example 2. Example 3 has a structure similar to that in FIG. 6.

As a result of performing the discharge test in a similar manner as in Example 1, it was confirmed that there is no discharge trace on the semiconductor wafer and the abnormal discharge was suppressed.

### Comparative Example 1

A gas hole member and an electrostatic chuck device of Comparative Example 1 were obtained in a similar manner as in Example 1 except that only aluminum oxide (Al₂O₃) particles having an average particle diameter of 0.1 μm were used as a starting material.

Volume resistivity was measured in a similar manner as in Example 1. As a result, the volume resistivity of the gas hole member of Comparative Example 1 was larger than 1.0×10¹¹.

As a result of performing the discharge test in a similar manner as in Example 1, a discharge trace was observed in the semiconductor wafer, and it was confirmed that the abnormal discharge was not suppressed.

### Comparative Example 2

A gas hole member and an electrostatic chuck device of Comparative Example 2 were obtained in a similar manner as in Example 1 except that only silicon carbide (SiC) particles having an average particle diameter of 0.03 μm were used as a starting material.

Volume resistivity was measured in a similar manner as in Example 1. As a result, the volume resistivity of the gas hole member of Comparative Example 2 was smaller than 1.0×10³ Ω·cm.

As a result of performing the discharge test in a similar manner as in Example 1, it was confirmed that a temperature near the gas hole member rises and the plasma resistance is poor.

### Comparative Example 3

An electrostatic chuck device of Comparative Example 3 was obtained in a similar manner as in Example 1 except that a mixing ratio of the Al₂O₃ particles and the SiC particles was changed to obtain a gas hole member having volume resistivity of 1.0×10¹¹ Ω·cm.

As a result of performing the discharge test in a similar manner as in Example 1, a discharge trace was observed in the semiconductor wafer, and it was confirmed that the abnormal discharge was not suppressed.

By comparing Examples 1 to 3 with Comparative Examples 1 to 3, it was confirmed that the electrostatic chuck device including the member having volume resistivity of 10³ Ω·cm or more and 10¹⁰ Ω·cm or less in the gas hole can suppress the abnormal discharge.

### INDUSTRIAL APPLICABILITY

It is desirable to provide an electrostatic chuck device capable of suppressing abnormal discharge near a gas hole.

From the above results, it was confirmed that the present invention is useful.

### REFERENCE SIGNS LIST

1A, 1B Electrostatic chuck device
2A, 2B, 2C Electrostatic chuck plate
2s Placement surface
2p Rear surface
3 Base
3a Support surface
3b Lower surface
11 Dielectric substrate
11x Lower surface
13 Adsorption electrode
13h Retreat hole
15 Through-hole
16 Power supply terminal
17 Terminal through-hole
21 Power supply
23 Terminal insulator
24 Insulator
30 Passage route of gas
30A, 30B Gas hole
31 First through-hole
32 Second through-hole
33 Recessed portion
39 Fine hole
40 Gas hole member
45, 451, 452 Gas hole forming portion
50, 55 Adhesive layer
G Gas
W Wafer (sample)

1. An electrostatic chuck device comprising:
an electrostatic chuck plate including a dielectric substrate having a placement surface on which a sample is mounted, and an adsorption electrode located inside the dielectric substrate; and
a base that supports the electrostatic chuck plate from a side opposite to the placement surface,
wherein the electrostatic chuck plate has a gas hole passing through the electrostatic chuck plate in a thickness direction of the electrostatic chuck plate,
a gas hole member allowing a gas for cooling the sample to pass is provided in the gas hole, and
volume resistivity of a material of the gas hole member is 1.0×10³ Ω·cm or more and 1.0×10¹⁰ Ω·cm or less.

2. The electrostatic chuck device according to claim 1,
wherein the material of the gas hole member is a composite material of an insulating material and a conductive material.

3. The electrostatic chuck device according to claim 2,
wherein the dielectric substrate and the gas hole member are formed of the same material.

4. The electrostatic chuck device according to claim 1,
wherein the gas hole member is a porous body.

5. The electrostatic chuck device according to claim 1,
wherein the gas hole member has one or more fine holes having a diameter of 0.03 mm or more and 0.15 mm or less which pass through the gas hole member in the thickness direction.

6. An electrostatic chuck device comprising:
an electrostatic chuck plate including a dielectric substrate having a placement surface on which a sample is mounted, and an adsorption electrode located inside the dielectric substrate; and
a base that supports the electrostatic chuck plate from a side opposite to the placement surface,
wherein the electrostatic chuck plate has a gas hole passing through the electrostatic chuck plate in a thickness direction of the electrostatic chuck plate,
the dielectric substrate includes a gas hole forming portion at a position which overlaps the gas hole in a plan view,
the gas hole includes, at the gas hole forming portion,
a recessed portion which is provided on a surface which is opposite to the placement surface, and
a fine hole which is opened from the placement surface to the recessed portion,
a diameter of the fine hole is 0.03 mm or more and 0.15 mm or less, and
volume resistivity of a material of the gas hole forming portion is 1.0×10³ Ω·cm or more and 1.0×10¹⁰ Ω·cm or less.

7. The electrostatic chuck device according to claim 6,
wherein the dielectric substrate and the gas hole forming portion are formed of the same material.
